(19) United States
(12) Patent Application Publication
(10) Pub. No.: US 2015/0050756 A1
(43) Pub. Date: Feb. 19, 2015

(54) METHOD OF MANUFACTURING ORGANIC LIGHT-EMITTING DISPLAY APPARATUS

(71) Applicant: Samsung Display Co., Ltd., Yongin-City (KR)

(72) Inventors: Su-Hyuk Choi, Yongin-City (KR); Jin-Woo Park, Yongin-City (KR); Jai-Hyuk Choi, Yongin-City (KR)

(73) Assignee: Samsung Display Co., Ltd., Yongin-City (KR)

(21) Appl. No.: 14/260,444

(22) Filed: Apr. 24, 2014

(30) Foreign Application Priority Data
Aug. 16, 2013 (KR) 10-2013-0097319

(51) Int. Cl. H01L 21/66; H01L 51/52; H01L 51/56

(52) U.S. Cl. CPC H01L 22/12; H01L 51/56; H01L 51/5237
USPC 438/16

(57) ABSTRACT

A method of manufacturing an organic light-emitting display apparatus includes providing an organic light-emitting device including a first electrode, a second electrode and an intermediate layer including an organic emission layer, on a substrate; forming a pre-thin film encapsulation layer including an inorganic layer including a low temperature viscosity (“LVT”) inorganic material, on the organic light-emitting device; and selectively irradiating a beam having certain energy to a local area of the pre-thin film encapsulation layer.

This application claims priority to Korean Patent Application No. 10-2013-0097319, filed on Aug. 16, 2013, and all the benefits accruing therefrom under 35 U.S.C. §119, the disclosure of which is incorporated herein in its entirety by reference.

### BACKGROUND

1. Field

One or more exemplary embodiment of the invention relates to a method of manufacturing an organic light-emitting display apparatus.

2. Description of the Related Art

The use of a display apparatus has been diversified. Particularly, as the thickness and the weight of the display apparatus decrease, the range of the use of the display apparatus widens. Among the display apparatuses, an organic light-emitting display apparatus is a self-luminescent display apparatus having good power consumption properties, good viewing angles and/or good image quality.

An organic light-emitting display apparatus includes a first electrode, a second electrode, and an organic light-emitting device disposed therebetween and including at least an organic emission layer.

Since the organic light-emitting device is weak against and easily damaged by external moisture and heat, an encapsulation structure for encapsulating the organic light-emitting device is employed to protect the organic light-emitting device from external moisture and heat.

### SUMMARY

One or more exemplary embodiment of the invention includes a method of manufacturing an organic light-emitting display apparatus including a thin film encapsulation layer.

Additional features will be set forth in part in the description which follows and, in part, will be apparent from the description, or may be learned by practice of the presented exemplary embodiments.

According to one or more exemplary embodiment of the invention, a method of manufacturing an organic light-emitting apparatus includes providing an organic light-emitting device including a first electrode, a second electrode and an intermediate layer including an organic emission layer, on a substrate; forming a pre-thin film encapsulation layer including an inorganic layer including a low temperature viscosity (“LVT”) inorganic material, on the organic light-emitting device; and selectively irradiating a beam having certain energy to a local area of the pre-thin film encapsulation layer.

The above method may further include inspecting the pre-thin film encapsulation layer to identify defects in the pre-thin film encapsulation layer, after the forming the pre-thin film encapsulation layer and before the irradiating the beam.

The above method may further include generating information on a position of the defects in the pre-thin film encapsulation layer.

The irradiating of the beam may be conducted by using the information on the defects in the pre-thin film encapsulation layer obtained through the inspecting the pre-thin film encapsulation layer.

The irradiating of the beam may include locally irradiating the beam to an area corresponding to the defects and an area adjacent thereto, by using the information on the defects in the pre-thin film encapsulation layer obtained through the pre-thin film encapsulation layer.

The inspecting the pre-thin film encapsulation layer may include an optical inspecting method.

The optical inspecting method may be conducted by using an optical member, and the inspecting the pre-thin film encapsulation layer may be conducted while moving the optical member or the substrate.

The optical inspecting method may be conducted by using an automatic optical inspection (“AOI”) apparatus.

The defects may include an environmental element, a formation element, a pin hole, a separation space around the formation element or a separation space around the environmental element.

The environmental element may include impurity particles present or generated during manufacturing of the organic light-emitting display apparatus.

The formation element may include an agglomerated particle of the LVT inorganic material which may not participate in the forming the pre-thin film encapsulation layer.

The irradiating the beam may include irradiating the beam to provide energy sufficient to locally fluidize the LVT inorganic material of the pre-thin film encapsulation layer.

A defect among the defects in the pre-thin film encapsulation layer may be cured through the irradiating the beam.

The beam may include a laser beam, an ion beam, an electron beam (e-beam), a neutral beam or a plasma beam.

The above method may further include disposing a cooling member adjacent to the substrate. The irradiating the beam may be conducted with the cooling member adjacent to the substrate including the organic light-emitting device and the pre-thin film encapsulation layer disposed thereon.

A viscosity transition temperature of the LVT inorganic material may be a lowest temperature capable of providing fluidity to the LVT inorganic material.

The LVT inorganic material may include tin oxide.

The LVT inorganic material may further include at least one of phosphorus oxide, boron phosphate, tin fluoride, niobium oxide, tungsten oxide, aluminum (Al), carbon (C), ZnO, B₂O₃, and BiO.

The LVT inorganic material may include at least one of SnO; SnO and P₂O₅; SnO and BPO₄; SnO, SnF₂ and P₂O₅; SnO, SnF₂, P₂O₅ and NbO; or SnO, SnF₂, P₂O₅ and WO₃.

The LVT inorganic material may be provided by using a sputtering method, a vacuum deposition method, a low temperature deposition method, an electron beam coating method, an ion plating method, a chemical vapor deposition (“CVD”) method, a pulsed laser deposition (“PLD”) method, or a plasma spraying method.

### BRIEF DESCRIPTION OF THE DRAWINGS

These and/or other features will become apparent and more readily appreciated from the following description of the exemplary embodiments, taken in conjunction with the accompanying drawings in which:

FIG. 1 is a cross-sectional view schematically illustrating an exemplary embodiment of an organic light-emitting display apparatus, according to the invention;

FIGS. 2A to 2G are cross-sectional views illustrating an exemplary embodiment of a method of manufacturing the organic light-emitting display apparatus in FIG. 1; and

FIG. 3 is a cross-sectional view schematically illustrating another exemplary embodiment of an organic light-emitting display apparatus according to the invention.

### DETAILED DESCRIPTION

Reference will now be made in detail to exemplary embodiments, examples of which are illustrated in the accompanying drawings, wherein like reference numerals refer to the like elements throughout. In this regard, the illustrated exemplary embodiments may have different forms and should not be construed as being limited to the descriptions set forth herein. Accordingly, the exemplary embodiments are merely described below, by referring to the figures, to explain aspects of the invention. As used herein, the term “and/or” includes any and all combinations of one or more of the associated listed items. Expressions such as “at least one of,” when preceding a list of elements, modify the entire list of elements and do not modify the individual elements of the list. As used herein, the singular forms “a,” “an” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “formed on,” another layer, region, or component, it can be directly or indirectly formed on the other layer, region, or component. That is, for example, intervening layers, regions, or components may be present.

Sizes of elements in the drawings may be exaggerated for convenience of explanation. In other words, since sizes and thicknesses of components in the drawings are arbitrarily illustrated for convenience of explanation, the following exemplary embodiments are not limited thereto.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Spatially relative terms, such as “under,” “above,” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “under” relative to other elements or features would then be oriented “above” relative to the other elements or features. Thus, the exemplary term “under” can encompass both an orientation of above and below. The device may be otherwise oriented (rotated 90 degrees or at other orientations) and the spatially relative descriptors used herein interpreted accordingly.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, exemplary embodiments will be described in detail referring to accompanying drawings. In the drawings, the same or corresponding components will be given the same reference numerals, and explanation thereon will be omitted.

FIG. 1 is a cross-sectional view schematically illustrating an exemplary embodiment of an organic light-emitting display apparatus 100, according to the invention.

The organic light-emitting display apparatus 100 includes a substrate 101, an organic light-emitting device 120, and a thin film encapsulation layer 150 including an inorganic layer including a low temperature viscosity transition (“LVT”) inorganic material.

The substrate 101 may include various materials. In one exemplary embodiment, for example, the substrate 101 may include a transparent glass material including SiO₂ as a main component. Alternatively, the substrate 101 may include a transparent plastic material.

The organic light-emitting device 120 is disposed on the substrate 101 and includes a first electrode 121, a second electrode 122, and an intermediate layer 123. Particularly, the first electrode 121 is disposed on the substrate 101, the second electrode 122 is disposed on the first electrode 121, and the intermediate layer 123 is disposed between the first and second electrodes 121 and 122.

Even though not illustrated, a buffer layer may be disposed between the first electrode 121 and the substrate 101. The buffer layer may provide a planar surface on the substrate 101, and block moisture or gas penetrating through the substrate 101 from reaching the organic light-emitting device 120.

The first electrode 121 may function as an anode, and the second electrode 122 may function as a cathode. However, the polarity may be exchanged in an alternative exemplary embodiment.

When the first electrode 121 functions as an anode, the first electrode 121 may include a material having a relative high work function such as indium tin oxide (“ITO”), indium zinc oxide (“IZO”), ZnO, In₂O₃, or the like. According to the purpose and the design conditions of the invention, the first electrode 121 may further include a reflection layer (not shown) including Ag, Mg, Al, Pt, Pd, Au, Ni, Nd, Ir, Cr, Li, Yb, Ca, or the like.

When the second electrode 122 functions as a cathode, the second electrode 122 may include a metal such as Ag, Mg, Al, Pt, Pd, Au, Ni, Nd, Ir, Cr, Li, Ca, or the like. The second electrode 122 may include ITO, IZO, ZnO, In₂O₃, or the like to obtain a transparent layer.

The intermediate layer 123 includes one or more organic emission layer. Alternatively, the intermediate layer 123 may include an organic emission layer and selectively a layer among a hole injection layer, a hole transport layer, an electron transport layer and an electron injection layer.

When a voltage is applied to the first and second electrodes 121 and 122, visible light is generated from the intermediate layer 123, particularly from the organic emission layer of the intermediate layer 123.

Even though not illustrated, an exemplary embodiment of the organic light-emitting display apparatus 100 may further include a thin film transistor (not illustrated) electrically connected to the organic light-emitting device 120. The organic light-emitting display apparatus 100 may further include at least one capacitor electrically connected to the organic light-emitting device 120.

Even though not illustrated, a planarization layer or a passivation layer may be disposed between the organic light-emitting device 120 and the thin film encapsulation layer 150. The planarization layer and/or the passivation layer provides the organic light-emitting device 120 with a planar surface thereon and primarily passivates the organic light-emitting device 120. The planarization layer and/or the passivation layer may include various insulating materials. In one exemplary embodiment, for example, the planarization layer and/or the passivation layer may include an organic material.

The thin film encapsulation layer 150 is disposed on the organic light-emitting device 120.

The thin film encapsulation layer 150 includes the LVT inorganic material.

In the specification, the “viscosity transition temperature” does not mean a temperature inducing a complete change from a “solid state” to a “liquid state” of the LVT inorganic material, but means the lowest temperature at which the fluidity of the LVT inorganic material changes, that is, the lowest temperature of viscosity transition of the LVT inorganic material may be obtained.

The viscosity transition temperature of the LVT inorganic material may be lower than the transforming temperature of a material of the intermediate layer 123. In one exemplary embodiment, for example, the viscosity transition temperature of the LVT inorganic material of the thin film encapsulation layer 150 may be lower than the lowest transforming temperature of the material of the intermediate layer 123. The transforming temperature of the intermediate layer 123 means a temperature inducing a physical transformation and/or a chemical transformation of the material of the intermediate layer 123. A plurality of the transforming temperatures of the intermediate layer 123 may be present according to the kind and number of the materials of the intermediate layer 123. In one exemplary embodiment, for example, the viscosity transition temperature of the LVT inorganic material of the thin film encapsulation layer 150 and the transforming temperature of the intermediate layer 123 may mean a glass transition temperature (Tg) of the LVT inorganic material of the thin film encapsulation layer 150 and a Tg of an organic material of the intermediate layer 123.

The Tg of the LVT inorganic material of the thin film encapsulation layer 150 or the organic material of the intermediate layer 123 may be obtained by thermo gravimetric analysis (“TGA”). In exemplary embodiments, for example, the Tg of the material of the intermediate layer 123 may be obtained by thermal analysis using TGA and differential scanning calorimetry (“DSC”) (N₂ atmosphere, temperature range: from room temperature to about 600 degrees Celsius (° C.) (10° C./min)-TGA, from room temperature to about 400° C.-DSC, Pan type: Pt pan in disposable Al pan (TGA), in disposable Al pan (DSC)). The process would be easily recognized by a person skilled in the art.

The transforming temperature of the material of the intermediate layer 123 may exceed about 130° C., however, is not limited thereto. The transforming temperature of the material of the intermediate layer 123 may be easily measured through the above-described TGA.

The lowest transforming temperature of the material of the intermediate layer 123 may be, for example, from about 130° C. to about 140° C. In one exemplary embodiment, for example, the lowest transforming temperature of the material of the intermediate layer 123 may be about 132° C., and is not limited thereto. The lowest transforming temperature of the material of the intermediate layer 123 may be determined by obtaining the Tg of the material of the intermediate layer 123 through the above-described TGA, and selecting the lowest value among various Tg values.

The viscosity transition temperature of the LVT inorganic material of the thin film encapsulation layer 150 may be about 80° C. or above, for example, about 80° C. to about 132° C., and is not limited thereto. In one exemplary embodiment, for example, the viscosity transition temperature of the LVT inorganic material of the thin film encapsulation layer 150 may be about 80° C. to about 120° C., or about 100° C. to about 120° C. and is not limited thereto. In one exemplary embodiment, for example, the viscosity transition temperature of the LVT inorganic material of the thin film encapsulation layer 150 may be about 110° C.

The LVT inorganic material may include a single compound or a combination of two or more compounds.

The LVT inorganic material of the thin film encapsulation layer 150 may include tin oxide (for example, SnO or SnO₂). When the LVT inorganic material of the thin film encapsulation layer 150 includes SnO, the amount of SnO may be from about 20 wt % to about 100 wt % with respect to a total weight of the LVT inorganic material.

In addition to the tin oxide compound, the LVT inorganic material of the thin film encapsulation layer 150 may further include at least one of phosphorus oxide (for example, P₂O₅), boron phosphate (BPO₄), tin fluoride (for example, SnF₂), niobium oxide (for example, NbO), and tungsten oxide (for example, WO₃), and is not limited thereto.

The LVT inorganic material of the thin film encapsulation layer 150 may include the following compounds and is not limited thereto:
SnO;
SnO and P₂O₅;
SnO and BPO₄;
SnO, SnF₂, and P₂O₅;
SnO, SnF₂, P₂O₅, and NbO; or
SnO, SnF₂, P₂O₅, and WO₃.

The LVT inorganic material of the thin film encapsulation layer 150 may include the following compounds and is not limited thereto:

1) SnO (about 100 wt %);

2) SnO (about 80 wt %) and P₂O₅ (about 20 wt %);

3) SnO (about 90 wt %) and BPO₄ (about 10 wt %);

4) SnO (about 20-50 wt %), SnF₂ (about 30-60 wt %), and P₂O₅ (about 10-30 wt %) (where the sum of SnO, SnF₂, and P₂O₅ is about 100 wt %);

5) SnO (about 20-50 wt %), SnF₂ (about 30-60 wt %), P₂O₅ (about 10-30 wt %), and NbO (about 1-5 wt %) (Here, the sum of SnO, SnF₂, P₂O₅, and NbO is about 100 wt %); or

6) SnO (about 20-50 wt %), SnF₂ (about 30-60 wt %), P₂O₅ (about 10-30 wt %), and WO₃ (about 1-5 wt %) (Here, the sum of SnO, SnF₂, P₂O₅, and WO₃ is about 100 wt %).

In one exemplary embodiment, for example, the LVT inorganic material of the thin film encapsulation layer 150 may include SnO (about 42.5 wt %), SnF₂ (about 40 wt %), P₂O₅, (about 15 wt %), and WO₃ (about 2.5 wt %) and is not limited thereto.

The LVT inorganic material of the thin film encapsulation layer 150 may further include Al, C, ZnO, B₂O₃ or BiO.

In an exemplary embodiment of manufacturing the organic light-emitting display apparatus 100, when forming the thin film encapsulation layer 150 including the inorganic layer having the above-described composition, the viscosity transition temperature of the LVT inorganic material may be kept lower than the transforming temperature of the intermediate layer 123. Thus, various defects possibly formed in the thin film encapsulation layer 150 may be cured and/or removed during a subsequent irradiation process.

The thin film encapsulation layer 150 may include defects such as a formation element (not illustrated). The formation element may be inorganic particles, or other particles formed during forming the thin film encapsulation layer 150. The formation element may be cured during a subsequent irradiation process and form a portion of the thin film encapsulation layer 150.

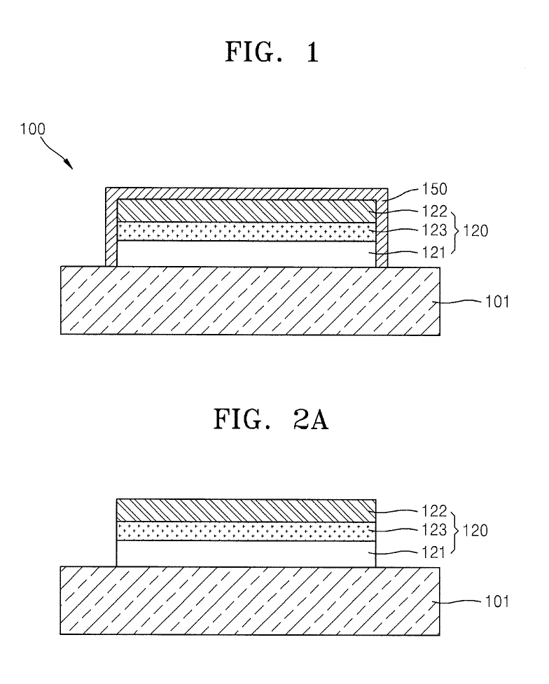

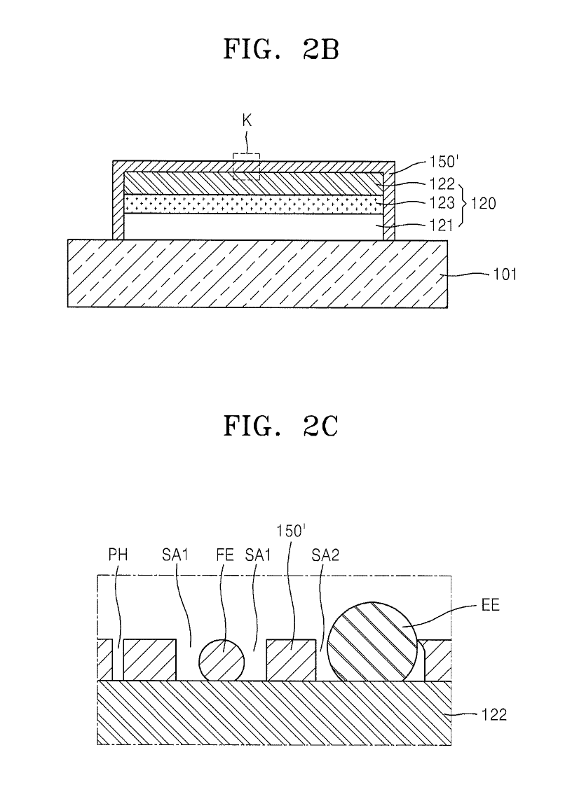

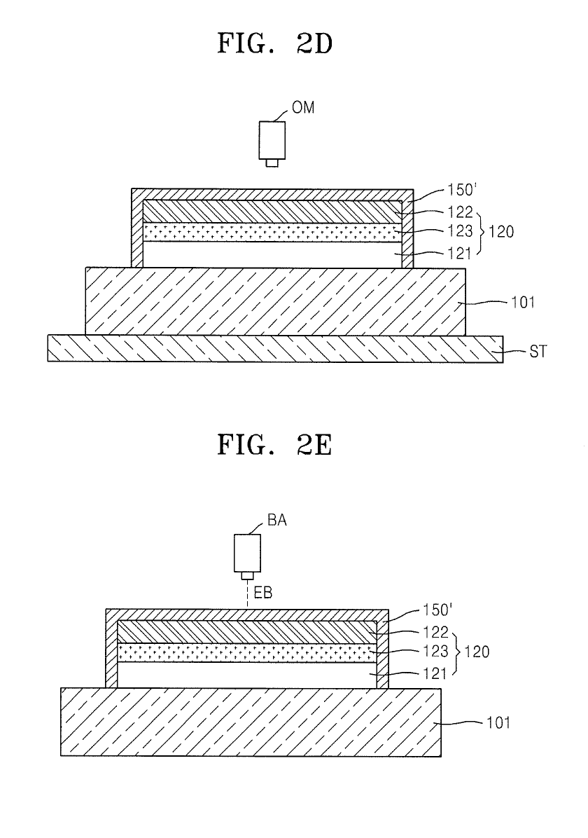

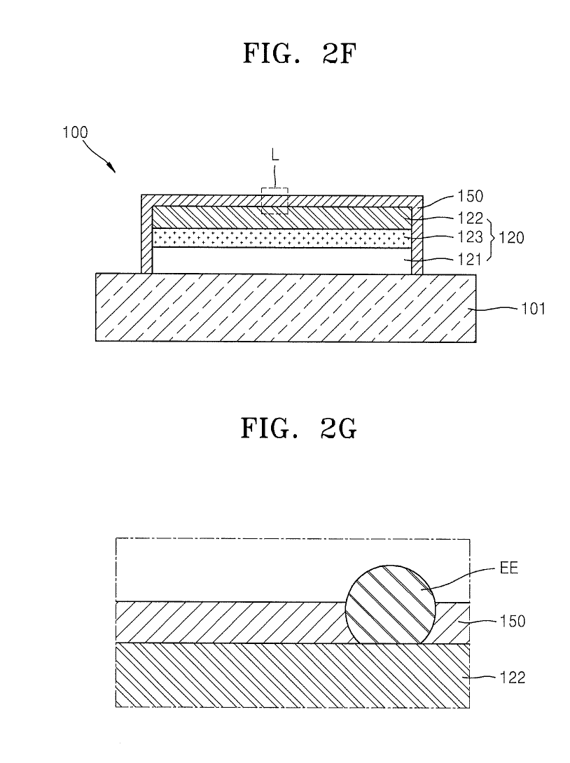

FIGS. 2A to 2G are cross-sectional views illustrating an exemplary embodiment of a method of manufacturing the organic light-emitting display apparatus 100 in FIG. 1.

Referring to FIG. 2A, the organic light-emitting device 120 is formed (e.g., provided) on the substrate 101. The organic light-emitting device 120 includes the first electrode 121, the second electrode 122 and the intermediate layer 123. The organic light-emitting apparatus 100 may further include a thin film transistor (not illustrated) and/or a capacitor (not illustrated) electrically connected to the organic light-emitting device 120 as described above.

Referring to FIG. 2B, a pre-thin film encapsulation layer 150′ is formed on the organic light-emitting device 120. The pre-thin film encapsulation layer 150′ is formed by using the LVT inorganic material described above. The pre-thin film encapsulation layer 150′ may be formed by using a sputtering method, a vacuum deposition method, a low temperature deposition method, an electron beam coating method or an ion plating method. Alternatively, the pre-thin film encapsulation layer 150′ may be formed by a chemical vapor deposition (“CVD”) method, a pulsed laser deposition (“PLD”) method, or a plasma spraying method.

FIG. 2C is an enlarged view of region ‘K’ in FIG. 2B. Referring to FIG. 2C, the pre-thin film encapsulation layer 150′ includes various defects. In one exemplary embodiment, for example, the pre-thin film encapsulation layer 150′ includes an environmental element EE, a formation element FE, a pin hole PH and separation areas SA1 and SA2.

The environmental element EE includes inevitable impurity particles present or generated during manufacturing the organic light-emitting display apparatus 100, for example, during forming the organic light-emitting device 120. The environmental element EE includes, for example, minute particles introduced from external environment (for example, dust, mote, etc.), remaining materials after use while forming the organic light-emitting device 120 (for example, minute particles of a material for forming the second electrode 122 remaining after forming the second electrode 122).

The environmental element EE may include various organic materials, inorganic materials, a combination of the organic material and the inorganic material, or the like. The removal of the environmental element EE after forming the organic light-emitting device 120 by a known method such as a wet process including a cleaning process is substantially impossible.

In one exemplary embodiment, for example, the environmental element EE may include particles having an average diameter of about 5 micrometers (μm) or less, for example, particles having an average diameter from about 1 μm to about 5 μm. However, the invention is not limited thereto.

The formation element FE means agglomerated particles of the LVT inorganic material of the pre-thin film encapsulation layer 150′ that did not participate in the formation of the pre-thin film encapsulation layer 150′ including the LVT inorganic material.

The pin hole PH means an area that is not provided with the LVT inorganic material and exposes the organic light-emitting device 120. The generation of the formation element FE may contribute to the formation of the pin hole PH.

The separation area SA1 is an empty space formed when the LVT inorganic material of the pre-thin film encapsulation layer 150′ is not supplied around the formation element FE. The separation area SA2 is an empty space formed when the LVT inorganic material is not supplied around the environmental element EE.

The above described defects of the pre-thin film encapsulation layer 150′ may provide a passage of external environmental materials such as moisture, oxygen, etc. during storing and driving of the organic light-emitting apparatus 100, and may be a factor of forming progressive dark spots in the organic light-emitting apparatus 100, thereby decreasing the lifetime of the organic light-emitting apparatus.

After forming the pre-thin film encapsulation layer 150′, one or more of the following processes for curing the defects is conducted.

Referring to FIG. 2D, an inspection operation is conducted. The inspection operation is a process of inspecting the pre-thin film encapsulation layer 150′ to identify various kinds of defects and confirming the positions of the defects within the pre-thin film encapsulation layer 150′.

The inspection operation may be conducted by using various methods. The presence of the defects, the size of the defects and/or the position of the defects may be confirmed by a visual inspection.

However, the above-described defects are very small and mostly have indistinguishable color from the pre-thin film encapsulation layer 150′, and an optical inspection may be used instead of the visual inspection.

To conduct the optical inspection, an optical member OM is disposed to face the pre-thin film encapsulation layer 150′ above the substrate 101 including the pre-thin film encapsulation layer 150′ formed thereon, and defects are identified and observed.

For convenience of the inspection, the inspection process may be conducted after disposing the substrate 101 including the pre-thin film encapsulation layer 150′ thereon, on a stage ST. Alternatively, inspection including a moving process such as a scanning process of the stage ST and/or the optical member OM may be conducted.

Selectively, the inspection may be conducted by using an automatic optical inspection (“AOI”) apparatus.

By conducting the inspection operation using the above-described methods, the position of the defects of the pre-thin film encapsulation layer 150′ is confirmed and information on the position is obtained. The information on the position may be information designated with respect to the substrate 101 by a coordinate.

In this case, the information on the size and the shape of the defects may be obtained along with the position of the defects.

Referring to FIG. 2E, an irradiation operation is conducted. In the irradiation operation, a desired area of the pre-thin film encapsulation layer 150′ is locally irradiated with a beam having certain energy by using the obtained information on the defects through the method illustrated in FIG. 2D.

Particularly, the irradiation operation includes irradiating a beam having certain energy by using an irradiation apparatus BA, and an area of the pre-thin film encapsulation layer 150′ corresponding to the defects described above is selectively irradiated with the beam EB. Among the above-described defects, for example, the pin hole PH and an area adjacent to the pin hole PH, are irradiated with the beam EB to cure the pin hole PH. Through the irradiation of the beam EB, the LVT inorganic material of the pre-thin film encapsulation layer 150′ may be fluidized to have flowability. The fluidized inorganic material may fill up the pin hole PH to effectively remove the pin hole PH.

Similarly, through locally irradiating the beam EB only to the formation element FE and the environmental element EE and to the areas adjacent thereto to cure the formation element FE and the environmental element EE, both of the separation area SA1 around the formation element FE and the separation area SA2 around the environmental element EE may be filled up with the fluidized LVT inorganic material of the pre-thin film encapsulation layer 150′.

The irradiation apparatus BA irradiates the beam EB having certain energy. The energy of the beam EB may be in a range that may generate the viscosity transition of the LVT inorganic material of the pre-thin film encapsulation layer 150′. That is, a beam having sufficient energy by which the LVT inorganic material may reach the viscosity transition temperature is supplied to the LVT inorganic material of the pre-thin film encapsulation layer 150′. The beam is supplied to the LVT inorganic material of the pre-thin film encapsulation layer 150′ while the pre-thin film encapsulation layer 150′ is disposed on the organic light-emitting device 120.

In one exemplary embodiment, for example, the beam irradiated from the irradiation apparatus BA includes various kinds of beams such as a laser beam, an ion beam, an electron beam (e-beam), a neutral beam, a plasma beam, or the like. In addition, the beam has a point shape, a line shape, or the like to correctly irradiate the defects.

The irradiation operation of the beam EB from the irradiation apparatus BA may be conducted under an oxygen atmosphere, an inert gas atmosphere, or a vacuum atmosphere, at various temperature conditions.

Even though not illustrated, a cooling member may be disposed under the substrate 101 to decrease damage to the organic light-emitting device 120 disposed under the pre-thin film encapsulation layer 150′ by heat, during the irradiation operation.

The thin film encapsulation layer 150 is formed through conducting the inspection operation and the irradiation operation as illustrated in FIG. 2F, and the manufacture of the organic light-emitting display apparatus 100 is completed.

FIG. 2G is an enlarged view of region ‘L’ in FIG. 2F. Referring to FIG. 2G, the pin hole PH, the formation element FE, and the separation areas SA1 and SA2 in the pre-thin film encapsulation layer 150′ are removed and/or “cured” through the irradiation operation. Particularly, the LVT inorganic material of the pre-thin film encapsulation layer 150′ is locally fluidized to fill up the pin hole PH, the separation area SA1, and the like.

In addition, the separation area SA2 around the environmental element EE is filled up with the LVT inorganic material and disappears. Thus, the penetration of external moisture and foreign materials through the interface of the environmental element EE is blocked. In FIG. 2G, a cross-sectional height of the environmental element EE is greater than a cross-sectional thickness of the thin film encapsulation layer 150. When the size of the environmental element EE is smaller than the cross-sectional thickness of the thin film encapsulation layer 150, the separation area SA2 around the environmental element EE may be fully filled up with the LVT inorganic material, and the thin film encapsulation layer 150 may be formed to cover all the environmental elements EE.

In the illustrated exemplary embodiment of the organic light-emitting display apparatus 100 according to the invention, the thin film encapsulation layer 150 is formed, and the organic light-emitting device 120 is easily encapsulated. Through decreasing the cross-sectional thickness of the thin film encapsulation layer 150, the organic light-emitting display apparatus 100 having good bending properties may be easily manufactured.

The thin film encapsulation layer 150 is formed by forming the pre-thin film encapsulation layer 150′ and conducting the inspection operation and the irradiation operation.

Through the inspection operation, the defects in the pre-thin film encapsulation layer 150′ may be easily confirmed, and through the irradiation operation, only the area corresponding to the defects may be locally irradiated with the beam having certain energy to easily cure the defects.

Through the above-described operations and processes, the thin film encapsulation layer 150, in which the defects are cured, may be formed in a relatively short time without applying an additional heat treating process to the pre-thin film encapsulation layer 150′.

Particularly, a heat treating process is not conducted on an entirety of the whole pre-thin film encapsulation layer 150′, and the irradiation operation is conducted on a local area in a short time. Thus, damage to the organic light-emitting device 120 may be fundamentally blocked.

In an alternative exemplary embodiment, a cooling member (not illustrated) may be disposed under the substrate 101 to double the passivation effect of the organic light-emitting device 120.

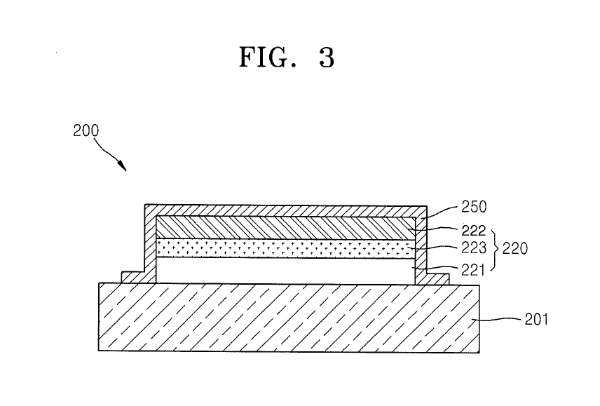

FIG. 3 is a cross-sectional view schematically illustrating another exemplary embodiment of an organic light-emitting display apparatus according to the invention.

Referring to FIG. 3, an organic light-emitting display apparatus 200 includes a substrate 201, an organic light-emitting device 220, and a thin film encapsulation layer 250.

The organic light-emitting device 220 includes a first electrode 221, a second electrode 222 and an intermediate layer 223.

For convenience of explanation, differences from the above-described exemplary embodiment will be explained in priority herein below.

The structure of the thin film encapsulation layer 250 is different in the exemplary embodiment in FIG. 3 from that in the above-described exemplary embodiment. The thin film encapsulation layer 250 has a structure covering the upper surface and the side surface of the organic light-emitting device 220. Thus, damage to the organic light-emitting device 220 due to moisture, external gas and foreign materials may be prevented.

In addition, the thin film encapsulation layer 250 contacts the substrate 201. Accordingly, the organic light-emitting device 220 may be effectively encapsulated by the thin film encapsulation layer 250. In addition, through the contact of the thin film encapsulation layer 250 and the substrate 201, the separation of the thin film encapsulation layer 250 from the organic light-emitting display apparatus 200 may be reduced or effectively prevented, and the durability of the thin film encapsulation layer 250 may be improved. Even though not illustrated, the thin film encapsulation layer 250 may contact an additionally disposed insulation layer and/or conductive layer on the substrate 210.

The materials for forming the organic light-emitting device 220 and the thin film encapsulation layer 250 are the same as those described in the above exemplary embodiment. Thus, a detailed description thereof is omitted.

As described above, according to one or more exemplary embodiment of the invention, through the method of manufacturing the organic light-emitting display apparatus, encapsulating properties of the organic light-emitting display apparatus may be easily improved.

It should be understood that the exemplary embodiments described herein should be considered in a descriptive sense only and not for purposes of limitation. Descriptions of features or elements within each exemplary embodiment should typically be considered as available for other similar features or aspects in other exemplary embodiments.

While one or more exemplary embodiments of the invention have been described with reference to the figures, it will be understood by those of ordinary skill in the art that various changes in form and details may be made therein without departing from the spirit and scope of the invention as defined by the following claims.

What is claimed is:

1. A method of manufacturing an organic light-emitting apparatus, the method comprising:
providing an organic light-emitting device comprising a first electrode, a second electrode, and an intermediate layer including an organic emission layer, on a substrate;
forming a pre-thin film encapsulation layer comprising an inorganic layer including a low temperature viscosity transition inorganic material, on the organic light-emitting device; and
selectively irradiating a beam having a certain energy to a local area of the pre-thin film encapsulation layer.

2. The method of claim 1, further comprising inspecting the pre-thin film encapsulation layer to identify defects in the pre-thin film encapsulation layer, after the forming the pre-thin film encapsulation layer and before the selectively irradiating the beam.

3. The method of claim 2, wherein the inspecting the pre-thin film encapsulation layer comprises generating information on a position of the defects in the pre-thin film encapsulation layer.

4. The method of claim 3, wherein the irradiating the beam to the local area of the pre-thin film encapsulation layer comprises using the information on the defects in the pre-thin film encapsulation layer obtained through the inspecting the pre-thin film encapsulation layer.

5. The method of claim 3, wherein the irradiating the beam comprises locally irradiating the beam to an area corresponding to the defects and an area adjacent thereto, by using the information on the defects in the pre-thin film encapsulation layer obtained through the inspecting the pre-thin film encapsulation layer.

6. The method of claim 2, wherein the inspecting the pre-thin film encapsulation layer comprises an optical inspecting method.

7. The method of claim 6, wherein
the optical inspecting method comprises using an optical member, and
the inspecting the pre-thin film encapsulation layer comprises moving the optical member or the substrate.

8. The method of claim 6, wherein the optical inspecting method comprises using an automatic optical inspection apparatus.

9. The method of claim 2, wherein the defects comprise an environmental element, a formation element, a pin hole, a separation space around the formation element or a separation space around the environmental element.

10. The method of claim 9, wherein the environmental element comprises impurity particles present or generated during manufacturing of the organic light-emitting display apparatus.

11. The method of claim 9, wherein the formation element comprises an agglomerated particle of the low temperature viscosity transition inorganic material which does not participate in the forming the pre-thin film encapsulation layer.

12. The method of claim 1, wherein the irradiating the beam comprises irradiating the beam which provides energy sufficient to locally fluidize the low temperature viscosity transition inorganic material of the pre-thin film encapsulation layer.

13. The method of claim 1, wherein a defect among the defects in the pre-thin film encapsulation layer, is cured through the irradiating the beam.

14. The method of claim 1, wherein the beam comprises a laser beam, an ion beam, an electron beam, a neutral beam or a plasma beam.

15. The method of claim 1, further comprising disposing a cooling member adjacent to the substrate,
wherein the irradiating the beam is conducted with the cooling member adjacent to the substrate including the organic light-emitting device and the pre-thin film encapsulation layer disposed thereon.

16. The method of claim 1, wherein a viscosity transition temperature of the low temperature viscosity transition inorganic material is a lowest temperature capable of providing fluidity to the low temperature viscosity transition inorganic material.

17. The method of claim 1, wherein the low temperature viscosity transition inorganic material comprises tin oxide.

18. The method of claim 17, wherein the low temperature viscosity transition inorganic material further comprises at least one of phosphorus oxide, boron phosphate, tin fluoride, niobium oxide, tungsten oxide, aluminum (Al), carbon (C), ZnO, B₂O₃ and BiO.

19. The method of claim 1, wherein the low temperature viscosity transition inorganic material comprises at least one of SnO; SnO and P₂O₅; SnO and BPO₄; SnO, SnF₂ and P₂O₅; SnO, SnF₂, P₂O₅ and NbO; or SnO, SnF₂, P₂O₅, and WO₃.

20. The method of claim 1, wherein the low temperature viscosity transition inorganic material is formed by using a sputtering method, a vacuum deposition method, a low temperature deposition method, an electron beam coating method, an ion plating method, a chemical vapor deposition method, a pulsed laser deposition method or a plasma spraying method.
